(19) United States
(12) Patent Application Publication
(10) Pub. No.: US 2017/0341075 A1
(43) Pub. Date: Nov. 30, 2017

(54) Methods and Apparatus for Coated Flowcells

(71) Applicant: IDEX Health & Science LLC, Oak Harbor, WA (US)

(72) Inventors: Jim Sirkis, Wallingford, CT (US); Meggie Grafton, Guilford, CT (US); Samad M. Edlou, Pittsford, NY (US)

(21) Appl. No.: 15/608,833

(22) Filed: May 30, 2017

Related U.S. Application Data
(60) Provisional application No. 62/342,726, filed on May 27, 2016.

(51) Int. Cl. B01L 3/00; C23C 14/10; C23C 14/58

(52) U.S. Cl. CPC B01L 3/502707; C23C 14/5826; C23C 14/5886; C23C 14/10; B01L 3/5027; B01L 2200/12; B01L 2300/0887; B01L 2300/12

(57) ABSTRACT

Microfluidic devises and process for making the devices include coating a substrate with an active oxygen layer and covalently bonding a polymeric microfluidic pattern to the substrate and devices made by the process.

### CROSS-REFERENCE TO RELATED APPLICATIONS

The application claims benefit of priority to U.S. Provisional Application No. 62/342,726, filed May 27, 2016, which is incorporated herein in its entirety by reference.

### BACKGROUND

Microfluidics revolves around the precise manipulation of fluids within geometries where at least one characteristic dimension is on the sub-millimeter scale. At these scales, physical properties such as surface tension, fluidic resistance and energy transfer play dominant roles and can present both challenges and benefits depending on the application. For example, Reynolds numbers in microfluidic devices are typically low, leading to laminar flow for all practical fluid velocities. Laminar flow means designers cannot rely on turbulence to mix fluids, but can leverage laminar flow to efficiently separate fluids and cells.

Microfluidics is a technology that has been found to be useful in varied fields of science and technology including engineering, physics, chemistry, biochemistry, nanotechnology, and biotechnology. Microfluidics involves systems in which low, sub-milliliter or microliter scale volumes of fluids are processed for automated parallel testing and high-throughput screening. Microfluidics are used in inkjet printheads, DNA chips, lab-on-a-chip technology, micro-propulsion, and micro-thermal technologies, for example.

Typically fluids are moved, mixed, separated or otherwise processed. Fluidic channels typically include one or more inlet ports and outlet ports for flow of one or more liquids through the channels in single or branched configurations. Channels can include wells or other sites that contain test or target compositions that react or bond with agents or indicators in the fluid. Numerous applications employ passive fluid control techniques like capillary forces. In some applications external actuators are additionally used for a directed transport of the media. Examples are rotary drives applying centrifugal forces for the fluid transport on the passive chips, pressure pumps, syringe pumps, peristaltic pumps, electro-osmotic pumps or piezoelectric pumps, for example. Active microfluidics refers to the defined manipulation of the working fluid by active (micro) components such as micropumps or micro valves. Micro pumps supply fluids in a continuous manner or can be used for dosing. Micro valves also can determine the flow direction or the mode of movement of pumped liquids. Often processes which are normally carried out in a lab are miniaturized on a single chip in order to enhance efficiency.

Many microfluidic devices used in the field of biotechnology for example include channels that are formed by a hydrophobic substance on a glass plate or slide, or etched into a silicon chip. Such devices are expensive to manufacture, limiting customizability and ability to purchase in large quantities for many research purposes. Customized layers with custom channel design have been used, but primarily with expensive glass substrates. The reliance on glass is due at least in part to challenges in effective bonding of the layers to alternative substrates that are either less expensive or lend themselves to uses for which glass is not appropriate such as thermal cycling, for example. There is a need in the art, therefore, for lower cost and easily customizable microfluidic devices or chips and for devices appropriate for a wider range of applications.

### SUMMARY

The disclosed apparatuses and methods provide the ability to tailor substrates for biological assays unique to each product and to be able to directly bond a variety of substrates to a polydimethylsiloxane (PDMS) layer, allowing the use of materials like plastic or metal for parts of the disclosed apparatuses which is less expensive than glass. The advantages offered by the disclosure include a much broader application of the flow cell technology and production of flow cells at a significantly reduced cost. The ability to combine several materials on a single chip increases the available range of life sciences applications, which can now include such methods as on-chip polymerase chain reaction (PCR) processes using a metal substrate for thermocycling, for example.

The disclosed apparatuses and processes are useful in a variety of techniques in the life sciences and other areas including, but not limited to immunoassays, genetic sequencing, SNP detection and other DNA analysis, micropneumatic systems (micro-pumps and micro-valves) enzymatic analysis, including polymerase chain reaction, clinical pathology and diagnostics, including point-of-care, immunology and cancer detection, detection of biochemical toxins and pathogens, cell separation, sorting, counting & manipulation, droplet manipulation and digital microfluidics, optofluidics, drug screening and delivery, neural cell study including axotomy, axon cutting and soma/axon separation and integrated lateral flow, among others. Irrespective of the specific application, microfluidic solutions offer the benefits of small volumes, leading to reduced reagent usage, small size and geometric flexibility, high degree of parallel reactions and fluid processes, greater control over fluid mixing and heating and faster reactions.

Coating a variety of materials with silicon dioxide (SiO₂) enables bonding between PDMS and atypical substrates. In the life sciences realm, carefully tailored substrates are used for various biological assays such as PCR, and cell, protein, or nucleic acid capture and analysis. Prior to developing the SiO₂ coating, a substrate and PDMS layer would typically be bonded through an adhesive layer, including in some examples, a two sided adhesive tape. Adhesives add a level of complexity for assembly and can contribute to bubbles in channels or between layers. Additionally, not all surfaces and materials are appropriate for adhesive bonding. In contrast to adhesives, using substrate materials with an SiO₂ layer enables covalent, irreversible bonding between the layers of a microfluidic device, creating a simpler assembly and more secure bonding.

This unique bonding enables the creation of complex flow cells combining machined plastic components with microchannels formed from PDMS layers and glass tops (for imaging). This is especially helpful for urology and hematology applications. In other applications a metal substrate provides high thermoconductivity for high heat transfer and low manufacturing costs (through machining, stamping, etc). In addition to being able to bond various substrates, the substrates themselves can then be rendered hydrophilic or amenable to surface functionalization because of the coating. This is of high importance for many genomic sequencing assays and other diagnostic devices.

Other uses for the disclosed coating may include as a blocking agent against air permeability or solvents. Again this is useful for tailoring the microenvironment for specific biological applications, such as a hypoxic chamber for tumor cell growth. In the same vein, coated PDMS membranes that maintain flexibility are useful in microvalves to increase the airtight seal and reduce bubble formation.

Components of the disclosed apparatus can include, but are not limited to (i) substrate material (aluminum, titanium, platinum, cyclic olefin copolymer (COC), acrylic, polyethylene terephthalate (PET), polystyrene, polycarbonate, and other suitable plastics and metals), (ii) PDMS layer, and (iii) SiO₂. SiO₂ can be layered onto the substrate via physical vapor deposition, optionally with an intermediate bonding assist layer. The SiO₂ coated substrate and PDMS are bonded together using oxygen plasma bonding, forming a covalent bond. The process provides important and novel advantages by allowing formation of a covalent bond between a plastic or metal substrate and PDMS using a biocompatible process.

Plastic substrates can be injection molded or machined with reservoirs, ports, microchannels or other components and then coated to bond to PDMS. The thin coating that can be about 1.6 nm to about 500 nm does not significantly affect the feature dimensions and, if necessary, features can be masked off and not coated to preserve original material properties and dimensions. Once the coating is applied, the substrate and PDMS layer/membrane are exposed to oxygen plasma to activate the surfaces. The two components are placed in contact and pressed to ensure a complete seal. The bonded pieces can be baked at about 20° C. to about 125° C. or about 50° C. to about 85° C. for 5-10 minutes to fully finish bonding. The fluid channels or other features of the device can be capped with either another layer of coated plastic or glass (following the same plasma procedure) to create an optically clear viewing region if desired, such as for assay analysis. If the surfaces are to be functionalized with silane, hydrogels or biological materials, there is a one hour time window to complete this step after plasma exposure. This ensures that the surfaces are hydrophilic and active to bond with the desired functional entities.

Similarly, coated metal substrates can be bonded to PDMS in the same fashion as plastic substrates by applying an oxygen plasma, pressing the parts together, and baking as described above. The substrate can be machined or molded with desired features prior to assembly or the metal can remain flat and features can be created in the PDMS layer. The assembly can then be capped with glass or plastic as required for the intended purpose.

The current disclosure can be described therefore, in certain embodiments as a method of preparing a substrate for bonding to a silicone surface comprising the steps of providing a substrate; cleaning at least one surface of the substrate; placing the substrate in a chamber under a vacuum within a preselected pressure range and within a preselected temperature range; optionally subjecting the at least one surface of substrate to an ion beam for a preselected time period; coating the at least one surface of the substrate with SiO₂ by subjecting the at least one surface of the substrate to physical vapor deposition of SiO₂ while optionally also subjecting the at least one surface of the substrate to an ion beam providing oxygen or argon ions; cleaning the SiO₂ coated substrate; subjecting the SiO2 coated surface of the substrate to oxygen plasma. In certain embodiments the silicone layer is polydimethylsiloxane (PDMS); and the method can further include treating the PDMS layer with oxygen plasma and contacting the at least one SiO₂ coated surface of the substrate to said PDMS layer.

It is an aspect of the disclosure that the described substrate can be composed of any suitable metal or polymeric material, including but not limited to aluminum, titanium, platinum, cyclic olefin copolymer (COC), acrylic, polyethylene terephthalate (PET), polystyrene, or polycarbonate. It is a further aspect of the disclosure that the substrate can be a portion of a microfluidics flow cell. In such embodiments the method can further include the step of attaching a layer of coated glass or a polymer to a second portion of the silicone layer and forming a flow cell. The method can also include creating or providing one or more of any of wells, channels, and features such as microchannels, ports, reservoirs, sensors, osmotic pumps, mixers, splitters, micro-electronic mechanical systems, or any combination thereof located at least partially in the substrate.

The current disclosure can also be described in certain embodiments as a product made by the processes described in the previous paragraphs, or more specifically as a flow cell including a substrate comprising aluminum, titanium, stainless steel, brass, or other alloy, a cyclic olefin copolymer, acrylic, polyethylene terephthalate, polyethylene, polypropylene, polystyrene, polycarbonate, or PEEK, and having a SiO₂ coating, wherein the SiO2 coating is bonded to a first surface of a PDMS layer. The flow cell can further include one or more biocompatible materials, or it can be made entirely of biocompatible materials and the substrate can include at least one hydrophilic surface. The flow cell can further include a layer of glass or a polymer securely attached to a second surface of said PDMS layer, wherein said first surface and said second surface of said PDMS layer are on opposite sides of said layer.

The current disclosure can also be described in certain embodiments as a method of coating a substrate for microfluidics comprising the steps of providing a substrate having a first side and a second side which comprises aluminum, titanium, stainless steel, brass, or other alloy, a cyclic olefin copolymer, acrylic, polyethylene terephthalate, polyethylene, polypropylene, polystyrene, polycarbonate, or PEEK, cleaning the substrate, placing the substrate in a chamber under a vacuum within a preselected pressure range of from about 1×10⁻⁶ Torr to about 1×10⁻⁵ Torr, and within a preselected temperature range of about 20° C. to about 90° C., or about 10° C. to about 125° C., or about 50° C. to about 85° C. subjecting at least one side of the substrate to an ion beam for a preselected time period, coating at least the same side of the substrate that was subjected to an ion beam with SiO₂ by subjecting at least that side of the substrate to physical vapor deposition of SiO₂ while also subjecting that side of the substrate to an ion beam radiation, cleaning the SiO₂ coated substrate, bonding the SiO₂ coated side of the substrate with the coating to polydimethylsiloxane (PDMS) using plasma bonding; and securely attaching to at least the side of the substrate bonded with PDMS a side of a layer of glass or a polymer, wherein that side of the layer comprises a PDMS bonded layer. The described method can further include providing one or more of any features such a wells, channels, microchannels, ports, reservoirs, sensors, osmotic pumps, mixers, splitters, micro-electronic mechanical systems or combinations of any thereof located at least partially in the substrate.

The current disclosure can also be described in certain embodiments as a flow cell, including a substrate having a surface, said substrate comprising aluminum, titanium, stainless steel, brass, or other alloy, a cyclic olefin copolymer, acrylic, polyethylene terephthalate, polyethylene, polypropylene, polystyrene, polycarbonate, or PEEK, a SiO₂ coating covalently bonded to said surface, and a layer of polydimethylsiloxane comprising a first surface covalently bonded to said SiO₂ coating. In certain embodiments such a flow cell can further include that the layer of polydimethylsiloxane comprises a second surface opposite said first surface wherein said second surface is covalently bonded to a cap, and can further include that the cap is composed of an optically transparent material such as, but not limited to glass for example. In certain embodiments the flow cell can include that the layer of polydimethylsiloxane includes one or more of fluid flow channels, and optionally that the substrate can include one or more of any of a number of features such as a microchannel, a port, a reservoir, a sensor, an osmotic pump, a mixer, a splitter, a micro-electronic mechanical system, or any combination thereof.

In certain embodiments, the present disclosure can be described as a process of manufacturing a microfluidic flow cell by providing a substrate, applying a coating to the substrate effective to produce a substrate with a chemically active surface comprising ionic oxygen or argon, providing a layer of PDMS comprising one or more fluid flow channels, and covalently bonding said chemically active surface to a layer of PDMS. This process can further include any of bonding a cap layer comprising glass to said layer of PDMS on the surface opposite the substrate, forming one or more fluid flow channels in said layer of PDMS prior to covalently bonding said chemically active surface to said layer of PDMS, forming one or more fluid flow channels in said layer of PDMS after covalently bonding said chemically active surface to said layer of PDMS, or any combination thereof.

The disclosure can also be described in certain embodiments as a process of manufacturing a microfluidic flow cell comprising providing a substrate; applying a coating to the substrate effective to produce a substrate with a chemically active surface comprising ionic oxygen; providing a layer of PDMS comprising one or more fluid flow channels; covalently bonding said chemically active surface to a layer of PDMS; and bonding a cap layer comprising glass to said layer of PDMS on the surface opposite the substrate. In any of the methods and products described herein, the fluid flow channels can be adapted for use in a variety of processes, including but not limited to an immunoassay, genetic sequencing, single nucleotide polymorphism (SNP) detection, polymerase chain reaction (PCR), genetic diagnostics, micropneumatic systems, enzymatic analysis, clinical pathology, clinical diagnostics, immunology, cancer detection, companion diagnostics, biochemical toxin or pathogen detection, cell separation, cell sorting, cell counting, cell manipulation, droplet manipulation, digital microfluidics, optofluidics, drug screening, drug delivery, neural cell study, axotomy, axon cutting, soma/axon separation, and integrated lateral flow. The methods and products disclosed herein can also include apparatus adapted for use in an inkjet printhead, a DNA chip, a lab-on-a-chip, micro-propulsion, or a micro-thermal technology.

The disclosure can also be described in certain embodiments as a process of producing a microfluidic device comprising the steps of: forming, molding or machining a substrate to comprise one or more of a microchannel, a port, a reservoir, a sensor, an osmotic pump, a mixer, a splitter, or a micro-electronic mechanical system, wherein said substrate can include aluminum, titanium, stainless steel, brass, or other alloy, a cyclic olefin copolymer, acrylic, polyethylene terephthalate, polyethylene, polypropylene, polystyrene, polycarbonate, or PEEK, wherein the process can include layering SiO₂ onto the substrate via physical vapor deposition optionally with an intermediate bonding assist layer to provide a SiO₂ coated substrate and/or forming, molding or machining a PDMS layer configured for use with the configuration of said substrate; and optionally covalently bonding said SiO₂ coated substrate with said PDMS layer using oxygen plasma bonding.

The described process can further include bonding a cap to the PDMS layer by exposing the PDMS layer and the cap to oxygen plasma to activate the surfaces, wherein the cap can include an optically clear viewing region, wherein the substrate can be injection molded or machined, wherein the substrate is coated with a layer of SiO₂ to a thickness of about 1.6 nm to about 550 nm and wherein covalently bonding said SiO₂ coated substrate with said PDMS layer comprises contacting the SiO₂ coated substrate with said PDMS layer, and applying pressure and heat to achieve bonding. In certain embodiments the substrate and PDMS layer are subjected to a temperature of about 20° C. to about 125° C. and pressure for from about 5 to about 10 minutes, or bonding the cap to the PDMS layer comprises contacting the cap with the PDMS layer and applying pressure and heat to achieve bonding, and in certain embodiments the cap and PDMS layer are subjected to a temperature of about 20° C. to about 125° C. and pressure for from about 5 to about 10 minutes.

The use of the term “or” in the claims is used to mean “and/or” unless explicitly indicated to refer to alternatives only or the alternatives are mutually exclusive, although the disclosure supports a definition that refers to only alternatives and “and/or.”

Throughout this application, the term “about” is used to indicate that a value includes the standard deviation of error for the device or method being employed to determine the value.

Following long-standing patent law, the words “a” and “an,” when used in conjunction with the word “comprising” in the claims or specification, denotes one or more, unless specifically noted.

Other objects, features and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

### BRIEF DESCRIPTION OF THE DRAWINGS

The accompanying drawings, which are incorporated in and constitute a part of this specification, illustrate an implementation of apparatus consistent with the present disclosure and, together with the detailed description, serve to explain advantages and principles consistent with the disclosure.

FIG. 1 is an example of a microfluidic device including a glass cap (top panel) for imaging or detection, a PDMS layer (middle panel) forming fluidic channels and an acrylic machine substrate (bottom panel) with any of fluidic channels, ports, reservoirs, sensors, osmotic pumps, mixers, splitters, or micro-electronic mechanical systems located at least partially in the substrate.

FIG. 2 is an example of processes of coating SiO₂ onto a substrate surface.

FIG. 3 is an example of a glass half-cell with bonded PDMS layer.

FIG. 4 is an example of a silicon coated titanium substrate.

FIG. 5 is an example of an assembled microfluidic device with transparent cap and fluid in the channels.

FIGS. 6, 7 and 8 are diagrams of a two channel microfluidic device, a single channel microfluidic device and a Y-mixer microfluidic device, respectively.

FIG. 9 is a schematic of a substrate with attached platinum electrodes disposed in a channel formed by a PDMS layer as prepared for SiO₂ coating.

### DESCRIPTION OF EMBODIMENTS

The above general description and the following detailed description are merely illustrative of the generic apparatus and method, and additional modes, advantages, and particulars will be readily suggested to those skilled in the art without departing from the spirit and scope of the disclosure.

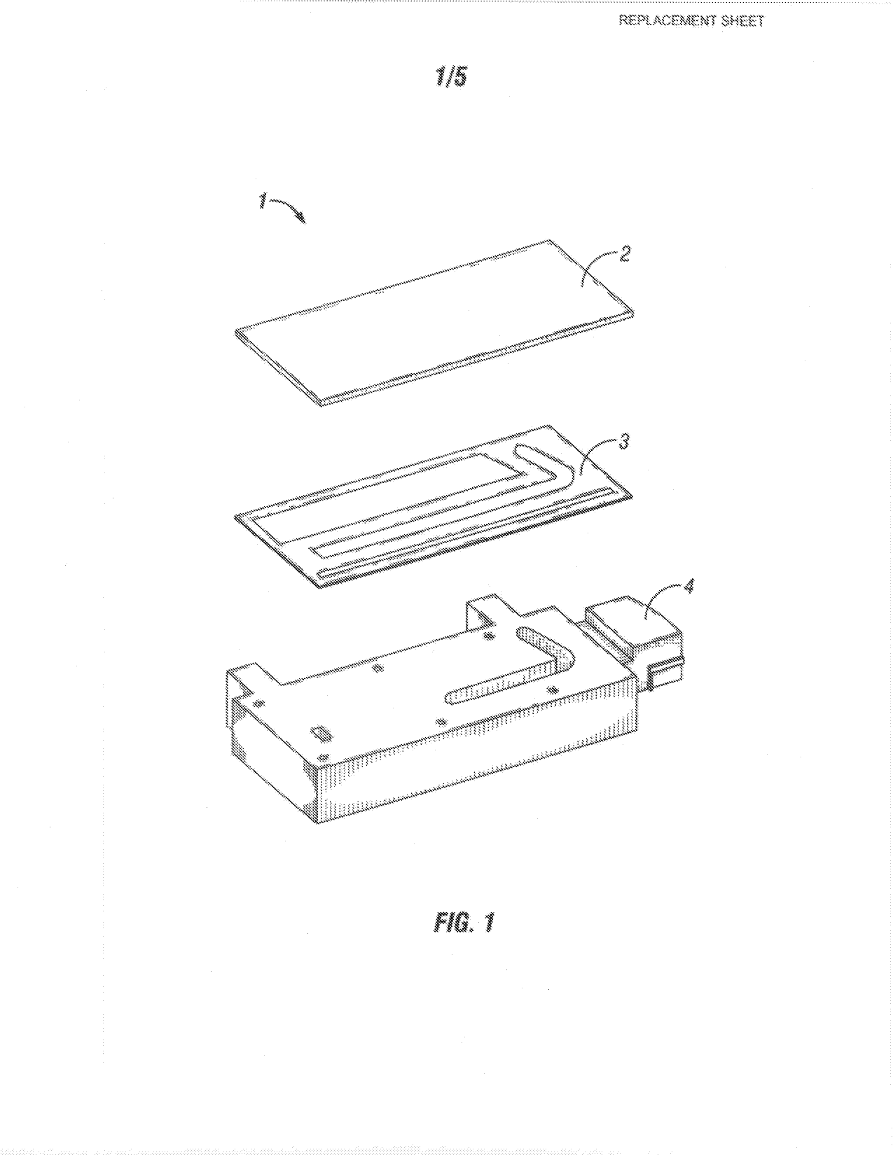

An example of a flow cell assembly 1 as shown in FIG. 1 can include a glass cap 2 for imaging or detection, a PDMS layer 3 forming fluidic channels and an acrylic machined substrate 4 with any of fluidic channels, ports, reservoirs, sensors, osmotic pumps, mixers, splitters, or micro-electronic mechanical systems formed and located at least partially in the substrate. An example of a process for making the assembly 1 is described below.

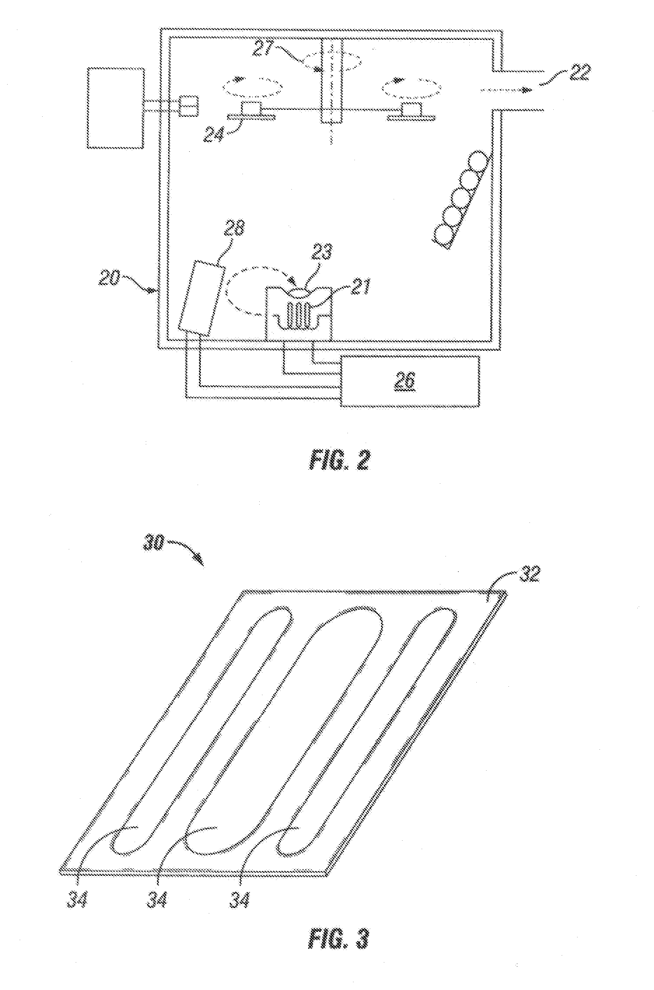

A schematic of an ion deposition and ebeam radiation chamber is shown in FIG. 2. As shown in the figure, the process is carried out in a vacuum chamber 20 that includes a port 22 connected to one or more vacuum pumps. The substrate 24 is placed on a rotor 27 providing complex planetary rotation as indicated by the circling arrows. As shown in FIG. 2, two substrates 24 may undergo the same process simultaneously. It will be appreciated that more than two substrates may undergo the process simultaneously. Power supplies 26 are connected to an ion source 28 within the chamber. A hot filament 21 provides a 270 degree path for the physical vapor deposition of SiO2 23.

An example of a glass half-cell 30 with bonded PDMS layer 32 is shown in FIG. 3. As seen in the figure, the PDMS layer 32 provides microchannels 34 for a fluid flow device.

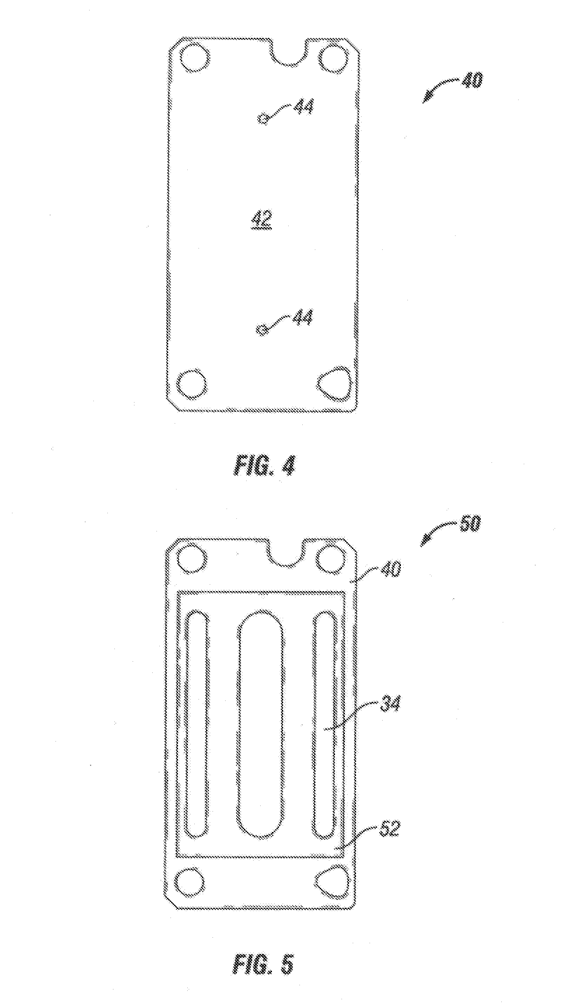

FIG. 4 is an example of a silicon coated titanium substrate 40. The substrate includes a flat surface 42 and openings 44 in the substrate for fluid flow.

FIG. 5 is an example of an assembled microfluidic device 50 with a substrate 40 as shown in FIG. 4, and with a transparent cap 52 and fluid in the channels 34 as shown in FIG. 3.

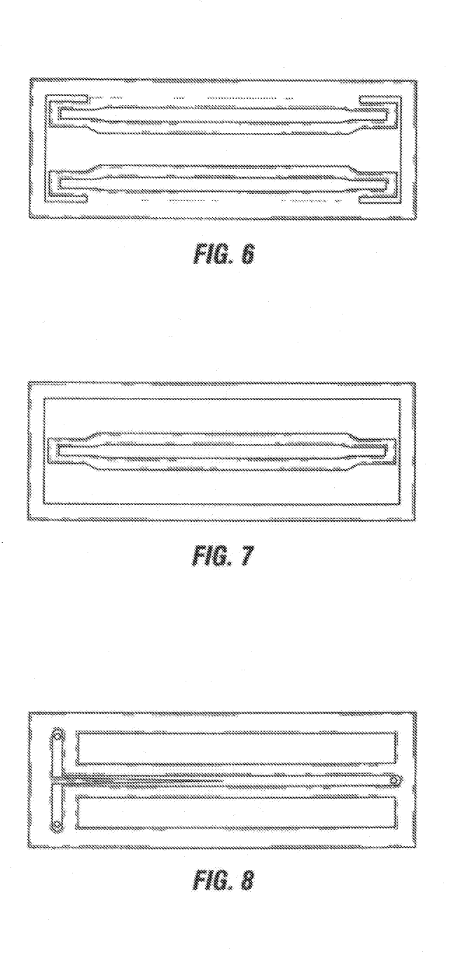

FIGS. 6, 7 and 8 are diagrams of a two channel microfluidic device, a single channel microfluidic device and a Y-mixer microfluidic device, respectively.

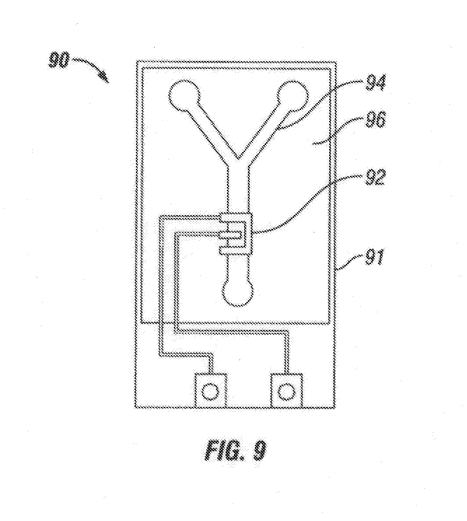

FIG. 9 is a schematic of a flow cell device 90 including substrate 91 with attached platinum electrodes 92 disposed in a channel 94 formed by a PDMS layer 96 as prepared for SiO₂ coating. As shown in FIG. 9, the flow cell assembly 90 may include electrodes 92 electrically connected to a power source, not shown in the FIG. 9. In the assembly shown in FIG. 9, the electrodes are platinum (although it will be appreciated that other conductive materials may be used). The platinum electrodes may be provided by depositing platinum on the surface of the substrate in a particular pattern or by etching the desired pattern after platinum has been deposited on the surface of the substrate. As shown in FIG. 9, the electrodes extend over and across the channel of the flow cell. In one particular embodiment, the electrodes can be used to determine an electrical characteristic of the fluid or material located in the channel, such as resistance, voltage or capacitance, for example, which may be helpful to determine the relative health or status of biological materials in the channel. In other applications, electrodes or other electrical devices (such as micro-electrical-mechanical systems, or MEMs) may be added to the substrate before coating the surface with the SiO₂ layer. For example, the electrodes may be included, but may be used to measure or determine things other than electrical resistance, such as electrochemical reactions as may be useful for glucose measurement or oxygen content measurement and the like. In addition, such electrodes or MEMs devices may include heating elements to provide thermocycling of some or selected portions of the flow cell assembly (e.g., certain portions of the channel, certain portions of the substrate, or the like). Such MEMs devices may also include devices for pumping a fluid or for color detection, or for other purposes. In the specific example shown in FIG. 9, the substrate comprises PET, but those skilled in the art will appreciate from the discussion in this disclosure that other materials may be used.

Examples of substrates and coating parameters is shown below in Table 1.

TABLE 1

| | | | Chamber Base | | | |
|---|---|---|---|---|---|---|
| | Coating | Start-End | Pressure | | Effective | |
| Substrate | Process | Temp. (° C. 0 | (Torr) | thickness(nm) | Bond? | Hydrophilic? |
| Acrylic | IAD with O₂ | 20-71 | 1.00 × 10⁻⁵ | 500 | Yes | Yes |
| | Ion Pre- | | | | | |
| | cleaning | | | | | |
| Acrylic | Conventional | 20-35 | 1.00 × 10⁻⁵ | 500 | yes | Yes |
| | e-beam | | | | | |
| Acrylic | Conv. E- | 30-46 | 1.00 × 10⁻⁵ | 500 | No, | No |
| | beam with | | | | None | |
| | O₂ ion pre- | | | | | |
| | cleaning | | | | | |
| COC | IAD with O₂ | 20-71 | 1.00 × 10⁻⁵ | 500 | yes | Yes |
| | Ion Pre- | | | | | |
| | cleaning | | | | | |
| COC | Conv. E- | 34-46 | 1.00 × 10⁻⁵ | 500 | yes | Yes |
| | beam with | | | | | |
| | O₂ ion pre- | | | | | |
| | cleaning | | | | | |
| COC | Conventional | 20-35 | 1.00 × 10⁻⁵ | 500 | yes | Yes |
| | e-beam | | | | | |
| PET | Conventional | 20-21 | 1.00 × 10⁻⁵ | 8.5 | Yes | Yes |
| | e-beam | | | | | |
| PET | Conventional | 20-23 | 1.00 × 10⁻⁵ | 17 | Yes | Yes |
| | e-beam | | | | | |
| PET | Conventional | 20-27 | 1.00 × 10⁻⁵ | 42 | Yes | Yes |
| | e-beam | | | | | |
| PET | Conventional | 20-23 | 1.00 × 10⁻⁵ | 4.5 | Yes | Yes |
| | e-beam | | | | | |
| PET | Conventional | 20-20 | 1.00 × 10⁻⁵ | 1.5 | Yes | Yes |
| | e-beam | | | | | |
| Polystyrene | IAD with O₂ | 20-72 | 9.00 × 10⁻⁶ | 500 | Yes | Yes |
| | Ion Pre- | | | | | |
| | cleaning | | | | | |
| Polystyrene | Conventional | 20-35 | 1.00 × 10⁻⁵ | 500 | Yes | Yes |
| | e-beam | | | | | |
| Polystyrene | Conv. E- | 20-43 | 9.5 × 10⁻⁶ | 500 | Yes | Yes |
| | beam with | | | | | |
| | O₂ ion pre- | | | | | |
| | cleaning | | | | | |
| Polycarbonate | Conventional | 20-35 | 1.00 × 10⁻⁵ | 500 | Yes | Yes |
| | e-beam | | | | | |
| Polycarbonate | Conv. E- | 34-46 | 1.00 × 10⁻⁵ | 500 | Yes | Yes |
| | beam with | | | | | |
| | O₂ ion pre- | | | | | |
| | cleaning | | | | | |
| Polycarbonate | IAD with O₂ | 20-72 | 1.00 × 10⁻⁵ | 500 | Yes | Yes |
| | Ion Pre- | | | | | |
| | cleaning | | | | | |
| Anodized Al | IAD. Sub | 125-125 | 6.5 × 10⁻⁶ | 500 | Yes, | Yes |
| | M1 & SiO2 | | | | Best | |
| Anodized Al | IAD SiO2 | 125-125 | 9.00 × 10⁻⁶ | 500 | Yes | Yes |
| | Only | | | | | |

Coating Thickness Results

| | Thickness | Bond | |
|---|---|---|---|
| Material | (nm) | (Plasma) | Comments |
| PET Platinum | 42 | Yes | Bond as strong as glass |
| PET Platinum | 17 | Yes | Bond as strong as glass |
| PET Platinum | 8.5 | Yes | Bond as strong as glass |
| PET Platinum | 4.5 | Yes | Bond as strong as glass |
| PET Platinum | 1.6 | Yes | Bond as strong as glass |
| PET Platinum | 505 | Yes | Bond as strong as glass |

*Ion Assisted Deposition

An ion assisted physical vapor deposition process can be utilized to deposit the SiO₂ layer on the parts to be treated in a high vacuum coating chamber. The sequence of steps is as follows:

Parts are inspected, cleaned, placed in a custom coating fixture and loaded into a high vacuum coating chamber. The parts may be placed on surfaces which spin around a center axis and also which rotate around a central axis, similar to the Earth's rotation around its axis while rotating around the sun.

The vacuum chamber is pumped down to a base pressure of about 8×10⁻⁶ Torr, for titanium for example, or other vacuum strength based on the particular substrate.

During the pumpdown period, parts are heated to the appropriate temperature, such as about 125° C. for metal substrates, using substrate quartz lamp heaters.

After achieving the desired base pressure and temperature, parts are ion pre-cleaned for 3 minutes.

The SiO₂ layer is deposited with electron beam physical vapor deposition with O₂ plasma assist.

A quartz crystal monitor can be used to control coating deposition rate and thickness

After processing, coated substrates can be evaluated for effectiveness of bonding of the coating by an abrasion test. Hydrophilicity is evaluated with a water beading test.

Bonding strength of the SiO₂ to the substrates generally was observed to be as follows: Al/Titanium<acrylic/PET/COC/polystyrene/polycarbonate.

It was observed that the plastic polymers exhibit the best results all of which performed better than anodized aluminum or titanium. It is understood, however, that all tested materials are coated with sufficient efficiency for their intended use.

A test of bonding strength of a coated machined acrylic substrate tested in single channel layer with a glass cap demonstrated no failure of the microchannel when subjected to fluid flow at a pressure of at least 135 psi.

All SiO₂ coatings were approximately 1.6 nm to about 550 nm thick. In this example, the primary difference in treatment of the substrates was sample preparation (ion pre-cleaning, direct e-beam coating, or ion assisted deposition).

Due to low energy state (˜0.1 ev) the results from a typical conventional electron beam evaporation process often suffer from poor adhesion. Any particulate contamination on the substrates before deposition weakens the coating bonds, and can lead to flaking. An ion beam source as shown in FIG. 2 is used to direct high-energy oxygen ions at the substrate during the SiO₂ layer deposition. These incoming ions have far greater energy than the typical electron beam evaporate (on the order of 10-100 eV), and upon striking the substrate deposit this energy into the existing layers of the coating. Importantly, the energy is high enough to embed the oxygen ions down several nanometers into the coating, providing a dose of reactive gas to regions which may not have been fully oxidized before being covered by evaporate. Further, when the energy of the incoming ions is deposited into the coating, surface atoms from the coating are liberated to move and shift along the surface. This helps create an amorphous, non-crystalline solid, removing the columnar structure that promoted water absorption and creating a denser and more durable thin layer of SiO₂.

Uncoated substrates showed little to no bonding with PDMS.

In cases of glass substrates, films that are deposited at lower substrate temperature can then be baked or annealed at much higher temperature to achieve the desired optical and mechanical properties. Generally substrates made from plastics cannot be heated over 120° C. and generally should be kept below 80° C.-90° C. during the layer deposition. Therefore unlike glass substrates, plastic substrates must be coated at much lower temperature and can't be annealed after coating. However to achieve desired coating properties sometimes this limitation for the plastic substrates can be moderated by using an energetic coating process like Ion Assisted Deposition (IAD) during the layer deposition. A Mark II ion source with Oxygen plasma (O₂ ions) was used in IAD coated samples and ion pre-cleanings.

Variation of the IAD Parameters:

| O2 Flow rate (SCCM**) | Anode Voltage (V) | Anode Current (A) |
|---|---|---|
| 15-36 | 70-180 | 1-4 |

SiO₂ deposition rates: 1.5 A°/Sec-5° A/Sec for both conventional & IAD
depositions.
**Standard Cubic Centimeters per Minute

Those skilled in the art will understand that the methods and apparatus described in the foregoing disclosure can be modified or varied without departing from the scope of the disclosure, and that the methods and apparatus described will have uses, advantages and applications beyond the specific examples provided above. For example, it will be appreciated that the methods and apparatus described can be used to manufacture complex flow cells at least in part because of the ability to combine machined plastic or polymeric parts with microchannels and glass tops (such as for imaging purposes), which can be especially useful in applications for hematology and urology. In addition, the apparatus of the present disclosure may have some or all surfaces that are hydrophilic or amenable to surface immobilization. Moreover, the ability to use materials with relatively high thermoconductivity (such as aluminum, titanium, and other metals) allows the creation of flow cells and other apparatus which allow for relatively high heat transfer properties, yet still have relatively lower manufacturing costs and are generally easier to make (such as by machining, stamping, and the like). It will also be appreciated that the methods and apparatus of the present disclosure should allow for applications with blocking with respect to air permeability or solvents, such as using PDMS to impede air permeability in microvalves. The apparatus of the present disclosure can have a wide range of useful applications, including applications involving water cooling (such as a heat exchanger), PCR, patterned and/or functionalized surfaces with self-assembled monolayers, proteins, antibodies, aptamers, oligonucleotides, extracellular matrix components for cell DNA or RNA capture or detection, ELISA assays, organ on a chip or cell culture on a chip applications (which typically will involve tightly engineered microenvironments), electrophoresis, microreactors, and solvent or air permeability barriers.

All of the devices, apparatuses and methods disclosed and claimed herein can be made and executed without undue experimentation in light of the present disclosure. While the devices and methods of this invention have been described in terms of preferred embodiments, it will be apparent to those of skill in the art that variations may be applied to the devices and/or methods and in the steps or in the sequence of steps of the methods described herein without departing from the concept, spirit and scope of the invention. All such similar substitutes and modifications apparent to those skilled in the art are deemed to be within the spirit, scope and concept of the invention as defined by the appended claims.

We claim:

1. A method of coating a microfluidics substrate comprising the steps of:
providing a substrate having a first side and a second side wherein the substrate comprises a metal or a polymer;
coating at least the first or second side of the substrate by subjecting at least one of the first or second side of the substrate to physical vapor deposition of SiO₂ to produce an SiO₂ coated substrate;
providing a first layer of material comprising polydimethylsiloxane; and
bonding an SiO₂ coated side of the substrate to the polydimethylsiloxane layer with plasma bonding.

2. The method of claim 1, wherein the substrate comprises aluminum, titanium, a cyclic olefin copolymer, acrylic, or polyethylene terephthalate.

3. The method of claim 1, further comprising the step of subjecting the at least one side of the substrate to an ion beam concurrent with the physical vapor deposition step.

4. The method of claim 3, wherein the ion beam provides oxygen or argon ions to the substrate.

5. The method of claim 3, wherein the ion beam is applied to the substrate at a reduced pressure and increased temperature relative to ambient.

6. The method of claim 5, wherein the ion beam is applied within a pressure range of 1×10⁻⁶ Torr to 1×10⁻⁵ Torr, and within a temperature range of 20° C. to 125° C.

7. The method of claim 1, further comprising attaching a second layer comprising glass or a polymer to the at least one side of the substrate that is bonded with a polydimethylsiloxane layer.

8. The method according to claim 1 further comprising the step of providing one or more of microchannels, ports, reservoirs, sensors, osmotic pumps, mixers, splitters, micro-electronic mechanical systems, or combinations thereof located at least partially in the substrate.

9. The method of claim 1 wherein the first layer and the substrate comprise a flow cell.

10. The method of claim 1, wherein the substrate is coated with a layer of SiO₂ to a thickness of about 1.6 nm to about 550 nm.

11. The method of claim 1, wherein bonding said SiO₂ coated substrate with said polydimethylsiloxane layer comprises contacting the SiO₂ coated substrate with said polydimethylsiloxane layer, and applying pressure and heat to achieve bonding.

12. The method of claim 11 wherein the substrate and polydimethylsiloxane layer are subjected to a temperature of about 20° C. to about 125° C. and pressure for about 5 to about 10 minutes.

13. The method of claim 7 wherein bonding the cap to the polydimethylsiloxane layer comprises contacting the cap with the polydimethylsiloxane layer and applying pressure and heat to achieve bonding.

14. The method of claim 42, wherein the cap and PDMS layer are subjected to a temperature of 20° C. to about 72° C. and pressure for from about 5 to about 10 minutes.

15. A process of manufacturing a microfluidic flow cell comprising:
providing a substrate;
applying a coating comprising SiO₂ while concurrently applying an electron beam to the substrate effective to produce a substrate with a chemically active surface comprising ionic oxygen or argon;
providing a layer comprising polydimethylsiloxane comprising a first surface and a second surface said layer comprising one or more fluid flow channels; and
covalently bonding said chemically active surface to a first surface of said layer comprising polydimethylsiloxane.

16. The process of claim 15, further comprising bonding a cap layer comprising glass to said second surface of said layer of polydimethylsiloxane.

17. The process of claim 16 wherein said one or more fluid flow channels are formed in said layer of polydimethylsiloxane prior to covalently bonding said chemically active surface to said layer of polydimethylsiloxane.

18. The process of claim 16 wherein said one or more fluid flow channels are formed in said layer of polydimethylsiloxane after covalently bonding said chemically active surface to said layer of polydimethylsiloxane.

19. A flow cell comprising:
a substrate comprising aluminum, titanium, a cyclic olefin copolymer, acrylic, or polyethylene terephthalate, and having a first surface having thereon a coating comprising SiO₂, wherein the SiO₂ coating is bonded to a polydimethylsiloxane layer.

20. The flow cell according to claim 19 wherein said flow cell comprises one or more biocompatible materials.

21. The flow cell according to claim 19 wherein at least one surface of said substrate is hydrophilic.

22. The flow cell according to claim 19 further comprising a layer comprising glass or a polymer, wherein said layer comprises a polydimethylsiloxane coating and is attached to said substrate.

23. A flow cell comprising:
a substrate having a surface, said substrate comprising aluminum, titanium, a cyclic olefin copolymer, acrylic, or polyethylene terephthalate,
a SiO₂ coating covalently bonded to said surface, and
a layer of polydimethylsiloxane comprising a first surface covalently bonded to said SiO₂ coating.

24. The flow cell of claim 23 wherein said layer of polydimethylsiloxane comprises a second surface opposite said first surface wherein said second surface is covalently bonded to a cap.

25. The flow cell of claim 23, wherein said cap comprises an optically transparent material.

26. The flow cell of claim 23, wherein said cap comprises glass.

27. The flow cell according to claim 23 wherein layer of polydimethylsiloxane comprises one or more fluid flow channels.

28. The flow cell of claim 23, wherein said substrate comprises one or more of a microchannel, a port, a reservoir, a sensor, an osmotic pump, a mixer, a splitter, or a micro-electronic mechanical system.

29. The flow cell of 23, wherein said fluid flow channels are designed for use in an immunoassay, genetic sequencing, single nucleotide polymorphism (SNP) detection, polymerase chain reaction (PCR), genetic diagnostics, micropneumatic systems, enzymatic analysis, clinical pathology, clinical diagnostics, immunology, cancer detection, companion diagnostics, biochemical toxin detection, pathogen detection, cell separation, cell sorting, cell counting, cell manipulation, droplet manipulation, digital microfluidics, optofluidics, drug screening, drug delivery, neural cell study, axotomy, axon cutting, soma/axon separation, or integrated lateral flow.

30. The flow cell of claim 23, wherein said fluid flow channels are designed for use in an inkjet printhead, a DNA chip, a lab-on-a-chip, micro-propulsion, or a micro-thermal technology.

31. The flow cell of claim 23, wherein the substrate remains bonded to the polydimethylsiloxane layer when subjected to a fluid pressure of 135 psi.
